(19) United States
(12) Patent Application Publication
(10) Pub. No.: US 2010/0078064 A1
(43) Pub. Date: Apr. 1, 2010

(54) MONOLITHICALLY-INTEGRATED SOLAR MODULE

(75) Inventor: KEVIN MICHAEL COAKLEY, PALO ALTO, CA (US)

Correspondence Address: THE SMALL PATENT LAW GROUP LLP, 225 S. MERAMEC, STE. 725T, ST. LOUIS, MO, 63105, US

(73) Assignee: THINSILICION CORPORATION, MOUNTAIN VIEW, CA (US)

(21) Appl. No.: 12/569,510

(22) Filed: Sep. 29, 2009

Related U.S. Application Data
(60) Provisional application No. 61/101,022, filed on Sep. 29, 2008.

(51) Int. Cl. H01L 31/052; H01L 31/18

(52) U.S. Cl. 136/246; 438/73; 257/E31.11

(57) ABSTRACT

A solar module includes a substrate, a plurality of electrically interconnected solar cells, and an upper separation gap. The solar cells are provided above the substrate. At least one of the solar cells includes a reflective electrode, a silicon layer stack and a light transmissive electrode. The reflective electrode is provided above the substrate. The silicon layer stack includes an n-doped layer provided above the reflective electrode, an intrinsic layer provided above the n-doped layer and a p-doped layer provided above the intrinsic layer. The light transmissive electrode is provided above the silicon layer stack. The upper separation gap is provided between the cells. The upper separation gap electrically separates the light transmissive electrodes in the solar cells from one another such that the light transmissive electrode of one of the solar cells is electrically connected to the reflective electrode of another one of the solar cells.

### CROSS-REFERENCE TO RELATED APPLICATIONS

This application claims priority benefit to U.S. Provisional Application No. 61/101,022, entitled “Monolithically-Integrated Solar Module,” and filed Sep. 29, 2008 (the “'022 Application”). The entire disclosure of the '022 Application is incorporated by reference herein in its entirety.

### BACKGROUND OF THE INVENTION

The subject matter herein generally relates to solar cells, more particularly, to systems and methods for monolithically-integrating solar cells into solar modules.

Solar modules convert incident light into electricity. The solar modules include several solar cells electrically connected in series with one another. Each solar cell may include a stack of multiple semiconductor layers sandwiched between a top electrode and a bottom electrode. The top electrode of one solar cell is electrically connected to the bottom electrode of a neighboring solar cell. The stack of semiconductor layers includes an intrinsic semiconductor layer sandwiched between a pair of doped semiconductor layers. Some known solar cells include a P-I-N stack of semiconductor layers, which means that the stack of semiconductor layers includes a bottom, first deposited layer of p-doped semiconductor material, a middle intrinsic, or lightly doped, semiconductor material deposited on the bottom layer, and a top layer of n-doped semiconductor material that is deposited on the intrinsic layer. Other known solar cells include an N-I-P stack of semiconductor layers, which means that the stack of semiconductor layers includes a bottom layer of n-doped semiconductor material, a middle intrinsic, or lightly doped, semiconductor material, and a top layer of p-doped semiconductor material.

Light that is incident on the solar cells strikes the semiconductor layer stack. Photons in the light excite electrons and cause the electrons to separate from atoms in the semiconductor layer stack. Complementary positive charges, or holes, are created when the electrons separate from the atoms. The electrons drift or diffuse through the semiconductor layer stack and are collected at one of the top and bottom electrodes. The holes drift or diffuse through the semiconductor layer stack and are collected at the other of the top and bottom electrodes. The collection of the electrons and holes at the top and bottom electrodes generates a voltage difference in each of the solar cells. The voltage difference in the solar cells may be additive across the solar module. For example, the voltage difference in each of the solar cells is added together if the solar cells are connected in series.

Electric current and voltage is generated by the flow of electrons and holes through the top and bottom electrodes and between neighboring solar cells. The voltage generated by each solar cell is added in series across the solar cells in the solar module. The current is then drawn from the solar module for use in an external electrical load.

With respect to the P-I-N semiconductor layer stack in some known solar cells, the interdiffusion of boron from a p-doped amorphous or microcrystalline silicon layer in the semiconductor layer stack into the middle intrinsic amorphous or microcrystalline silicon layer in the semiconductor layer stack can lead to junction contamination within the semiconductor layer stack. Junction contamination within the semiconductor layer stack may reduce the efficiency of the solar module. For example, in known P-I-N solar cells having amorphous semiconductor layer stacks and in which the p-layer is deposited before the i- and p-layers, a “p/i contamination effect” may result. The p/i contamination effect is the interdiffusion of the dopant used to form the p-layer and may include boron, for example. The amount of interdiffusion of the boron into the intrinsic layer can be related to the temperature at which the intrinsic and n-doped semiconductor layers are deposited. As a result, the amount of p/i contamination increases with increasing deposition temperatures of the intrinsic and n-doped layers.

In order to reduce the amount of p/i contamination, known solar cells having P-I-N semiconductor layer stacks employ lower deposition temperatures for the deposition of the intrinsic and n-doped semiconductor layers. For example, some known solar cells may use deposition temperatures that are lower than approximately 220 degrees Celsius. Deposition temperatures above approximately 220 degrees Celsius may result in sufficient p/i contamination to result in an overall reduction in the efficiency of the solar cell in converting incident light into electricity. On the other hand, in the absence of dopant interdiffusion between the semiconductor layers in the P-I-N semiconductor layer stack, the quality and electronic properties of the silicon films in the semiconductor layer stacks tend to improve at higher deposition temperatures.

One manner for reducing the magnitude of the p/i contamination effect in solar cells at high deposition temperatures is to deposit the p-doped semiconductor layer after deposition of the intrinsic semiconductor layer in an N-I-P semiconductor layer stack. Depositing the p-doped layer after the intrinsic layer reduces the amount of time that the p-doped layer is exposed to increased deposition temperatures. For example, the time required to deposit the p-doped layer may only constitute a small fraction of approximately 5% or less of the total time required to deposit the N-I-P layer stack. As the amount of deposition time is reduced, the amount of diffusion of the boron dopant in the p-doped layer into the intrinsic layer decreases. Moreover, the p-doped layer can be deposited at lower deposition temperatures with little or no negative impact on the efficiency of the solar cell. Depositing the p-doped layer at lower deposition temperatures (for example, 220 degrees Celsius or lower) may allow the temperature of the surface of the intrinsic layer to be kept relatively low during the initial deposition of the p-doped layer. If the p-doped layer is deposited using a plasma enhanced method such as Plasma Enhanced Chemical Vapor Deposition (PECVD), the interaction of the plasma with the surface of the intrinsic layer when the p-doped layer is deposited may significantly enhance interdiffusion of the boron in the p-doped layer into the intrinsic layer at elevated temperatures.

Some known solar cells having an N-I-P semiconductor layer stack include a substrate along the bottom of the cell, a reflective electrode deposited on the substrate, an amorphous or microcrystalline n-doped silicon layer deposited on the reflective electrode, an amorphous or microcrystalline intrinsic silicon layer deposited on the n-doped layer, an amorphous or microcrystalline p-doped silicon layer deposited on the intrinsic layer, and a transparent electrode deposited on the p-doped layer. This configuration of layers may be referred to as a “substrate configuration” of a solar cell, with incident light striking the solar cell on a side opposite the substrate. Some known substrate configuration solar cells include a second semiconductor layer stack on top of the N-I-P semiconductor layer stack. These types of solar cells may be referred to as “tandem substrate configuration” solar cells. Another type of known solar cell is a “superstrate configuration” solar cell, in which the substrate is transparent to light and the incident light strikes the solar cell on the same side as the substrate. The substrate in the superstrate configuration may be referred to as a superstrate.

Known solar modules having several solar cells arranged in the substrate configuration or tandem substrate configuration solar cells include a substrate formed from a conductive material. For example, some known solar cells include a stainless steel substrate or a foil sheet formed from stainless steel that acts as the substrate. Manufacturing solar cells on stainless steel substrates is complicated by the fact that the steel is electrically conducting. In order to electrically connect the solar cells in series, as described above, the solar cells need to be electrically separated from one another by cutting the steel substrate into strips and then “stitching” individual cells back together using a conducting grid. These additional electrical separation steps increase the cost of manufacturing the solar modules.

If the stainless steel substrate is not cut into strips, the electrical conductivity of the steel can create an undesirable electric shunt, or short, between the reflective electrodes in adjacent cells. For example, the steel substrates may provide a conductive pathway with an area-specific resistance of less than 0.5 ohm*cm² between the reflective electrodes. In addition, in a series-connected module the top electrodes in adjacent solar cells need to be separated from one another so that a conductive pathway does not exist between the top electrodes in the adjacent cells that would provide an electric short between the cells during operation of the module.

Other known superstrate configuration and tandem superstrate configuration solar cells include a non-conducting, or dielectric, substrate. The electrodes and semiconductor layer stack(s) are deposited on the substrate and only the electrode and semiconductor layers are electrically isolated and interconnected to form a series connection between neighboring solar cells. This connection scheme in which the solar cells are interconnected on an insulating substrate is referred to as “monolithic integration.”

In the superstrate configuration of solar cells, the bottom electrode is a transparent electrode and the top electrode is a reflective electrode. Laser scribing is one known technique that may be used to pattern the electrode and semiconductor materials or films in a thin film solar module. The laser scribing of the superstrate configuration solar cells may be carried out in three steps: First, an ultraviolet (“UV”) or an infrared (“IR”) laser is used to pattern the bottom transparent electrode on glass immediately following deposition of the transparent bottom electrode; second, a visible light laser is fired through the superstrate and transparent electrode to remove the semiconductor layer immediately following deposition of the semiconductor layer; and third, a visible light laser is fired through the glass superstrate and the transparent bottom electrode to locally ablate both the semiconductor layer stack and the top reflective electrode immediately after deposition of the top reflective electrode. In the superstrate configuration, the laser light is transmitted through the transparent electrode into the semiconductor layers within a range of wavelengths that is absorbed by the semiconductor layers to explosively remove the layers. The laser light rapidly heats and vaporizes the semiconductor material, creating a pressure wave that leads to the explosive removal of the semiconductor material and the top reflective electrode.

The technique in which a laser is fired through the glass superstrate to pattern the semiconductor layer stack cannot be applied to known substrate configurations of solar cells. For example, a laser cannot be fired through the substrate and bottom reflective electrode in known substrate configuration solar cells to electrically isolate the semiconductor layer stack and the top transparent electrode. The bottom reflective electrode does not transmit the laser light over the wavelength range that is absorbed by the silicon. For example, the reflective electrode blocks the wavelengths of the laser light that would otherwise be used to ablate the semiconductor layer stack. As a result, the laser cannot explosively remove the semiconductor layers via illumination through the bottom reflective electrode.

Instead, both mechanical and laser scribing is required to separate the various layers in the solar cells in known substrate configuration solar modules. For example, mechanical scribing may be required to electrically separate the top electrodes of the solar cells in the module. Using a laser light to remove portions of the semiconductor layer stack and/or the top electrode may be problematic for at least one or more of the following reasons. The substrate may not permit the laser light to pass through the substrate and the bottom reflective electrode to selectively scribe the semiconductor layer stack and thus selectively remove both the semiconductor layer stack and the top light transmissive electrode. Moreover, the laser light may not be able to be applied through the top light transmissive electrode to remove the semiconductor layer stack and the top electrode. When the laser light is incident from above the solar cell and through the top electrode, the vaporized semiconductor material that forms when the laser light is absorbed is now formed on the top side of the semiconductor layer stack. The pressure wave that is created when the semiconductor material is vaporized extends toward the substrate and does not force the semiconductor material in a direction where the material can be easily removed from the module.

One known technique to compensate for the lack of explosive removal in the substrate configuration is to heat the semiconductor layers and/or the transparent electrode layer for a sufficient time with the laser that the entirety of the semiconductor and electrode layers are vaporized. But, heating the semiconductor and/or transparent electrode layers typically leads to a very large level of excess heat dissipation in the areas surrounding the semiconductor layers and electrode layer. The excess heat dissipation causes the electrode layers and the semiconductor layers to interdiffuse within one another in the regions proximate to the areas in which the laser is incident on the semiconductor layers. The intermixing of these layers may form an electrical shunt between adjacent solar cells and/or within a single solar cell. For example, the intermixing may form a conductive pathway between the top transparent electrode layers in adjacent solar cells or a conductive pathway between the electrode layers in a single solar cell. Electrically shorting the solar cells significantly reduces the efficiency and yield of the solar module.

### BRIEF DESCRIPTION OF THE INVENTION

In one embodiment, a solar module includes a substrate, a plurality of electrically interconnected solar cells, and an upper separation gap. The solar cells are provided above the substrate. At least one of the solar cells includes a reflective electrode, a silicon layer stack and a light transmissive electrode. The reflective electrode is provided above the substrate. The silicon layer stack includes an n-doped layer provided above the reflective electrode, an intrinsic layer provided above the n-doped layer and a p-doped layer provided above the intrinsic layer. The light transmissive electrode is provided above the silicon layer stack. The upper separation gap is provided between the cells. The upper separation gap electrically separates the light transmissive electrodes in the solar cells from one another such that the light transmissive electrode of one of the solar cells is electrically connected to the reflective electrode of another one of the solar cells.

In another embodiment, a method for manufacturing a solar module having a plurality of electrically interconnected solar cells includes providing a substrate, a reflective electrode, a silicon layer stack and a light transmissive electrode. The silicon layer stack includes an n-doped layer provided above the reflective electrode, an intrinsic layer provided above the n-doped layer and a p-doped layer provided above the intrinsic layer. The method also includes removing a portion of the light transmissive electrode to electrically separate the light transmissive electrodes in the solar cells from one another. The portion is removed by patterning the light transmissive electrode from a side of the solar module that opposes the substrate.

In another embodiment, another solar module is provided. The solar module includes a non-conducting substrate, a plurality of interconnected solar cells, and an upper separation gap. The solar cells are provided above the substrate. At least one of the solar cells includes a reflective electrode, a bottom silicon layer stack, a top silicon layer stack, and a light transmissive electrode. The reflective electrode is provided above the substrate. The bottom silicon layer stack includes an N-I-P layer stack that is deposited above the reflective electrode. The top silicon layer stack includes an N-I-P layer stack that is deposited above the bottom silicon layer stack. The light transmissive electrode is provided above the top silicon layer stack. The upper separation gap is provided between the cells and electrically separates the light transmissive electrodes in the solar cells from one another. The light transmissive electrode of one of the solar cells is electrically connected to the reflective electrode of another one of the solar cells.

### BRIEF DESCRIPTION OF THE DRAWINGS

FIG. 1 is a perspective view of a schematic diagram of a substrate configuration solar module and a magnified view of a cross-sectional portion of the solar module according to one embodiment.

FIG. 2 is schematic illustration of the magnified view of the solar module shown in FIG. 1 at one stage of fabrication of the solar module.

FIG. 3 is schematic illustration of the magnified view of the solar module shown in FIG. 1 at another stage of fabrication of the solar module.

FIG. 4 is a view of a laser scribe line used to create the gaps shown in FIGS. 2, 3 and/or 5.

FIG. 5 is schematic illustration of the magnified view of the solar module shown in FIG. 1 at another stage of fabrication of the solar module.

### DETAILED DESCRIPTION OF THE INVENTION

The foregoing summary, as well as the following detailed description of certain embodiments of the present invention, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. It should be noted that although one or more embodiments may be described in connection with a system for monolithically integrating silicon solar cells using lasers, the embodiments described herein are not limited to silicon-based solar cells or lasers. In particular, one or more embodiments may include a material other than silicon and/or employ a different patterning technique than laser scribing.

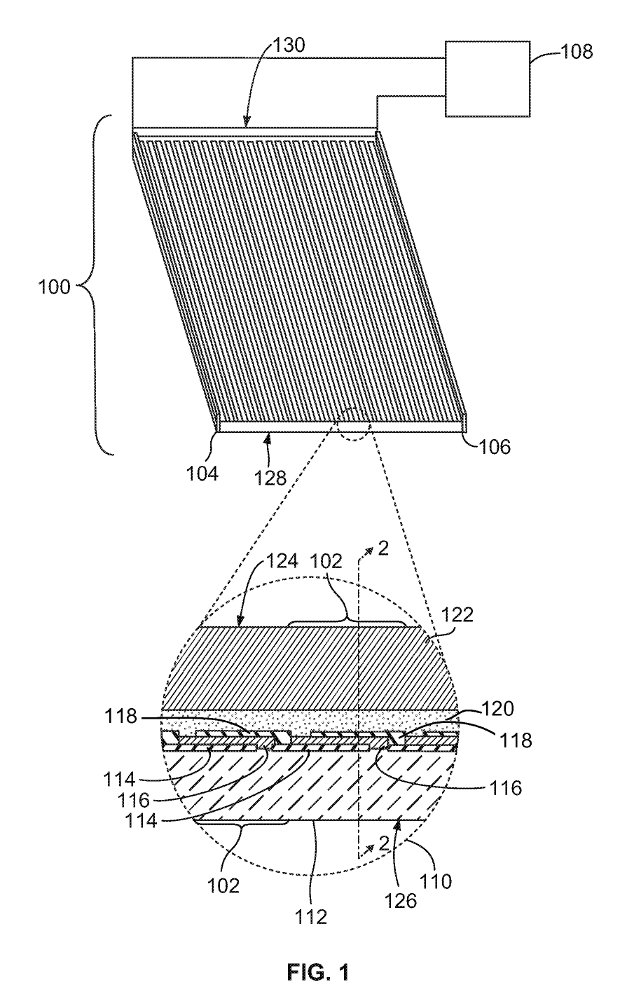

FIG. 1 is a perspective view of a schematic diagram of a substrate configuration solar module 100 and a magnified view 110 of a cross-sectional portion of the solar module 100 according to one or more embodiments. The solar module 100 may be referred to as a photovoltaic (“PV”) device 100. The solar module 100 includes a plurality of solar cells 102 electrically connected in series with one another. For example, the solar module 100 may have twenty-five or more solar cells 102 connected with one another in series. Each of the outermost solar cells 102 also may be electrically connected with one of a plurality of leads 104, 106. The leads 104, 106 extend between opposing ends 128, 130 of the solar module 100. The leads 104, 106 are connected with a circuit 108. The circuit 108 is a load to which the current generated by the solar module 100 is collected or applied.

Each of the solar cells 102 includes a stack of multiple layers. For example, the solar cells 102 may include a non-conducting substrate 112, a bottom electrode 114, a semiconductor layer stack 116, a top electrode 118, a top adhesive 120 and a cover sheet 122. The solar cells 102 in the solar module 100 may be electrically connected in series. The top electrode 118 of one solar cell 102 is electrically connected with the bottom electrode 114 in another solar cell 102. For example, the top electrode 118 in one solar cell 102 may be electrically connected with the bottom electrode 114 in a neighboring or adjacent solar cell 102 to provide a conductive pathway between the neighboring solar cells 102. The solar cells 102 in the solar module 100 thus are electrically connected in series. The semiconductor layer stack 116 includes at least three semiconductor layers. For example, the semiconductor layer stack 116 can include an N-I-P stack of semiconductor layers. Optionally, the semiconductor layer stack 116 can include two or three N-I-P stacks disposed on top of one another in a tandem semiconductor stack arrangement.

The solar module 100 generates electric current from light that is incident on a top surface 124 of the solar module 100. The top surface 124 of the solar module 100 may be referred to as the film side of the solar module 100. An opposing bottom surface 126 may be referred to as a substrate side of the solar module 100. The light passes through the cover sheet 122, the top adhesive 120 and the top electrode 118. The light is absorbed by the semiconductor layer stack 116. Some of the light may pass through the semiconductor layer stack 116. This light may be reflected back into the semiconductor layer stack 116 by the bottom electrode 114. Photons in the light excite electrons and cause the electrons to separate from atoms in the semiconductor layer stack 116. Complementary positive charges, or holes, are created when the electrons separate from the atoms. The electrons drift or diffuse through the semiconductor layer stack 116 and are collected at one of the top and bottom electrodes 118, 114. The holes drift or diffuse through the semiconductor layer stack 116 and are collected at the other of the top and bottom electrodes 118, 114. The collection of the electrons and holes at the top and bottom electrodes 118, 114 generates a voltage difference in the solar cells 102. The voltage difference in the solar cells 102 may be additive across the entire solar module 100. For example, the voltage difference in several of the solar cells 102 is added together. As the number of solar cells 102 electrically connected in series increases, the additive voltage difference across the series of solar cells 102 also may increase.

The electrons and holes flow through the top and bottom electrodes 118, 114 in one solar cell 102 to the opposite electrode 114, 118 in a neighboring solar cell 102. For example, if the electrons flow to the bottom electrode 114 in a first solar cell 102 when light strikes the semiconductor layer stack 116, then the electrons flow through the bottom electrode 114 to the top electrode 118 in the neighboring solar cell 102. Similarly, if the holes flow to the top electrode 118 in the first solar cell 102, then the holes flow through the top electrode 118 to the bottom electrode 114 in the neighboring solar cell 102.

Electric current and voltage is generated by the flow of electrons and holes through the top and bottom electrodes 118, 114 and between neighboring solar cells 102. The voltage generated by each solar cell 102 is added in series across the plurality of solar cells 102. The current is then drawn to the circuit 108 through the connection of the leads 104, 106 to the top and bottom electrodes 118, 114 in the outermost solar cells 102. For example, a first lead 104 may be electrically connected to the top electrode 118 in the left-most solar cell 102 while a second lead 106 is electrically connected to the bottom electrode 114 in the right-most solar cell 102.

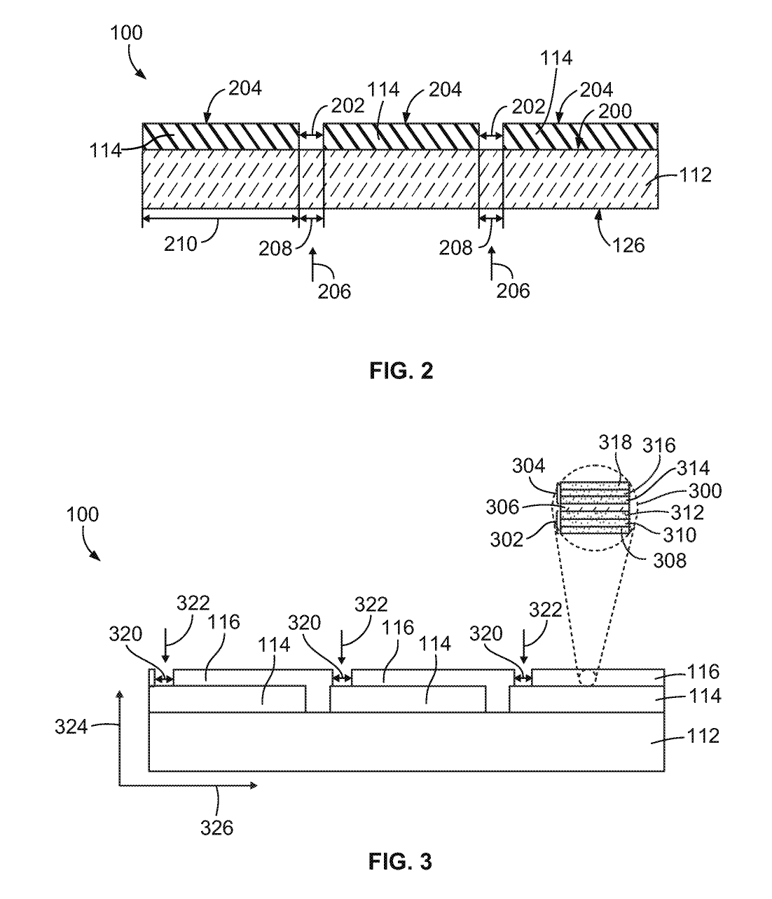

FIG. 2 is schematic illustration of the magnified view 110 of the solar module 100 at one stage of fabrication of the solar module 100. The substrate 112 includes a non-conducting material such as a glass sheet. The substrate 112 has an upper surface 200 that may be roughened prior to depositing any additional layers on the substrate 112. Roughening the upper surface 200 may improve the light scattering properties of the substrate 112. Improving the light scattering properties of the substrate 112 may improve the efficiency of the solar module 100 in converting incident light into electricity. The upper surface 200 may be roughened by sand blasting the upper surface 200.

The bottom electrode 114 is provided above the substrate 112. For example, the bottom electrode 114 may be deposited on the substrate 112 by sputtering the bottom electrode 114 onto the substrate 112. The bottom electrode 114 may be deposited continuously across the substrate 112. The illustration shown in FIG. 2 shows lower separation gaps 202 in the bottom electrode 114 caused by removal of portions of the bottom electrode 114, as described below. The bottom electrode 114 may be deposited such that no lower separation gaps 202 exist in the bottom electrode 114 after deposition of the bottom electrode 114. The bottom electrode 114 includes a light reflective, conductive material. For example, the bottom electrode 114 may include one or more of silver (Ag), aluminum (Al) and Nichrome (NiCr). In one embodiment, the bottom electrode 114 includes silver that is deposited on the substrate 112 at an elevated temperature, such as a temperature between approximately 100 to 500 degrees Celsius. Depositing silver on the substrate 112 at an elevated temperature can roughen the upper surface of the bottom electrode 114. The bottom electrode 114 may include a metal stack of a combination of these materials. For example, the bottom electrode 114 includes an approximately 30 nanometer thick layer of Nichrome deposited on the substrate 112, an approximately 100 to 500 nanometer thick layer of aluminum deposited on the Nichrome, and an approximately 50 to 500 nanometer thick layer of silver deposited on the aluminum.

An adhesion layer is provided below one or more of the conductive layers described above. For example, an adhesion layer that includes titanium (Ti), chromium (Cr), molybdenum (Mo), or Nichrome may be deposited below each of the metal layers in the bottom electrode 114 to assist in adhering the various layers in the bottom electrode 114 together.

In one embodiment, the bottom electrode 114 includes a buffer layer provided above the bottom electrode 114. For example, the buffer layer may be deposited on top of the conductive layer(s) described above. The buffer layer includes a material that stabilizes the conductive material(s) in the bottom electrode 114 and assists in preventing chemical diffusion of the conductive materials into the semiconductor layer stack 116 (shown in FIG. 1). For example, the buffer layer may reduce the amount of silver that diffuses into the semiconductor layer stack 116 from the bottom electrode 114. The buffer layer may reduce plasmon absorption losses in the semiconductor layer stack 116. The buffer layer is deposited by sputtering approximately 100 nanometers of the buffer layer on the conductive layers in the bottom electrode 114 in one embodiment. The conductive material(s) in the bottom electrode 114 may be roughened prior to sputtering the buffer layer on the conductive material(s) to assist in the adhesion of the buffer layer to the conductive material(s). Alternatively, the buffer layer may be deposited using a chemical vapor deposition technique, such as PECVD. The buffer layer may be deposited in a thickness of approximately 1 micron on the conductive material(s) of the bottom electrode 114. After deposition of the buffer layer, an upper surface 204 of the bottom electrode 114 may be roughened. The upper surface 204 may be roughened by chemically etching the buffer layer. For example, the upper surface 204 may be exposed to an acid such as a solution of 1% hydrochloric acid (HCl) and 99% water (H₂O) for approximately 2 minutes or less.

Portions of the bottom electrode 114 are removed to expose the lower separation gaps 202 in the bottom electrode 114. By way of example only, portions of the bottom electrode 114 may be removed by using a patterning technique on the bottom electrode 114 to selectively remove portions of the bottom electrode 114. In one embodiment, the patterning technique 206 is a laser light that scribes the lower separation gaps 202 in the bottom electrode 114. Alternatively, a source of energy other than a laser light may be used as the patterning technique 206. The patterning technique 206 may be a laser light that is directed into the bottom electrode 114 from the bottom, or substrate, side 126 of the solar module 100 in the illustrated embodiment. Optionally, the patterning technique may be a laser light 206 that may be directed into the bottom electrode 114 from the upper surface 204 of the bottom electrode 114. The laser light 206 passes through the substrate 112 to remove portions of the bottom electrode 114 in order to create the lower separation gaps 202. The lower separation gaps 202 have a width 208 in a direction parallel to the upper surface 200 of the substrate 112 of approximately 10 to 100 microns. In one embodiment, the width 208 is approximately 50 microns. After removing portions of the bottom electrode 114 to create the lower separation gaps 202, the remaining portions of the bottom electrode 114 are arranged as linear strips extending in directions transverse to the plane of FIG. 2. For example, the bottom electrode 114 may be arranged in linear strips transverse to the direction in which the width 208 is measured. The linear strips of the bottom electrode 114 have a width 210 in a direction parallel to the direction in which the width 208 is measured. The width 210 of the bottom electrode 114 linear strips is approximately 5 to 15 millimeters in one embodiment.

FIG. 3 is schematic illustration of the magnified view 110 of the solar module 100 at another stage of fabrication of the solar module 100. The semiconductor layer stack 116 is provided above the bottom electrode 114 and the substrate 112. For example, the semiconductor layer stack 116 may be deposited on the bottom electrode 114 and the substrate 112. The semiconductor layer stack 116 may be deposited on the substrate 112 in the lower separation gaps 202 (shown in FIG. 2) in the bottom electrode 114. In the embodiment illustrated in FIG. 1, the semiconductor layer stack 116 is deposited in each cell 102 between the top and bottom electrodes 118, 114 in a vertical direction 324 extending between the top and bottom surfaces 124, 126 of the module 100 and between the bottom electrodes 114 of adjacent cells 102 in a transverse direction 326.

As shown in a magnified view 300 of the semiconductor layer stack 116, the semiconductor layer stack 116 includes a tandem arrangement of two N-I-P stacks 302, 304 of silicon layers in the illustrated embodiment. The bottom stack 302 includes an N-I-P stack of silicon layers and the top stack 304 includes another N-I-P stack of silicon layers. An interlayer 306 may be provided between the top and bottom N-I-P stacks 302, 304. Alternatively, the interlayer 306 may not be included in the layer stack 116. The interlayer 306 includes a layer of material that at least partially reflects the incident light on the module 100. For example, the interlayer 306 may partially reflect the incident light back into the top stack 304 of N-I-P layers while permitting some of the light to pass through the interlayer 306 into the bottom stack 302. The interlayer 306 may include a material such as zinc oxide (ZnO), non-stoichiometric silicon oxide (SiOₓ) or silicon nitride (SiNₓ).

The semiconductor layer stack 116 may be provided by first providing a first layer 308 of microcrystalline n-doped silicon above the bottom electrode 114. For example, the first layer 308 may be deposited on the bottom electrode 114. Optionally, the first layer 308 of n-doped silicon is provided as an amorphous layer. The first layer 308 of n-doped silicon may be provided at a thickness of approximately 5 to 30 nanometers. The first layer 308 is deposited at a relatively high deposition temperature in one embodiment. For example, the first layer 308 may be deposited at a temperature of approximately 315 degrees Celsius. In another example, the first layer 308 may be deposited at a temperature of approximately 300 to 400 degrees Celsius. These temperatures are the temperatures of the substrate 112 in one embodiment. In another embodiment, the first layer 308 is deposited at a lower temperature. For example, the first layer 308 may be deposited at a substrate temperature of approximately 180 to 300 degrees Celsius.

A second layer 310 of intrinsic, or lightly doped, silicon is provided above the first layer 308. For example, the second layer 310 may be deposited on the first layer 308. The second layer 310 may be a microcrystalline or amorphous layer of silicon. The second layer 310 may be provided in a thickness greater than the first layer 308. By way of example only, a microcrystalline second layer 310 may be deposited at a thickness of approximately 2 microns or approximately 1 to 3 microns. As another example, an amorphous second layer 310 may be provided at a thickness of approximately 300 nanometers or approximately 200 to 400 nanometers. The second layer 310 may be deposited at a relatively high deposition temperature. For example, the second layer 310 may be deposited at a substrate temperature of approximately 300 to 400 degrees Celsius. Alternatively, the second layer 310 is deposited at a lower deposition temperature, such as 180 to 300 degrees Celsius.

A third layer 312 of p-doped silicon is provided above the second layer 310. For example, the third layer 312 may be deposited on the second layer 310. The third layer 312 is provided as a microcrystalline layer in one embodiment. Alternatively, the third layer 312 is provided as an amorphous layer. The third layer 312 may be deposited at a thickness that is slightly less than the thickness of the first layer 308. For example, the third layer 312 may be deposited at a thickness of approximately 5 to 20 nanometers. The third layer 312 may be deposited at a relatively low substrate temperature to reduce the interdiffusion of the dopant in the third layer 312 into the second layer 310. For example, the third layer 312 may be deposited at a substrate temperature of approximately 180 to 400 degrees Celsius. The interlayer 306 may be deposited on the third layer 312 in one embodiment.

A fourth layer 314 of n-doped silicon is provided above the interlayer 306. Alternatively, the fourth layer 314 is provided above the third layer 312. The fourth layer 314 may be deposited on the interlayer 306 or third layer 312 as an amorphous or microcrystalline layer of silicon. The fourth layer 314 may be provided at a thickness of approximately 5 to 30 nanometers or less. The fourth layer 314 is deposited at a substrate temperature of approximately 180 to 400 degrees Celsius in one embodiment. A fifth layer 316 of intrinsic, or lightly doped, silicon is provided above the fourth layer 314. The fifth layer 316 may be an amorphous layer of silicon. The fifth layer 316 may be provided at a thickness of approximately 70 to 300 nanometers in one embodiment. In another example, the fifth layer 316 is deposited at a thickness of approximately 200 to 400 nanometers. The fifth layer 316 may be deposited at a substrate temperature of 300 to 400 degrees Celsius. A sixth layer 318 of amorphous or microcrystalline p-doped silicon is provided above the fifth layer 315. The sixth layer 318 may be provided at a thickness of approximately 5 to 20 nanometers. The sixth layer 318 is provided at a relatively low substrate temperature to reduce the interdiffusion of the dopant in the sixth layer 318 into the fifth layer 316. For example, the sixth layer 318 may be deposited at a substrate temperature of approximately 180 to 400 degrees Celsius.

While the description herein describes the semiconductor layer 116 as including a tandem arrangement of semiconductor layers, other semiconductor layer stacks and/or interlayers may be included in the semiconductor layer 116. For example, the semiconductor layer stack 116 may include a single or multiple N-I-P stacks of amorphous silicon layers. Alternatively, the semiconductor layer stack 116 may include a single or multiple N-I-P stacks of microcrystalline silicon layers. In another example, the semiconductor layer stack 116 may include a triple junction layer stack in which the middle junction includes an n-doped microcrystalline silicon layer on the bottom of the junction, an amorphous layer of intrinsic, or lightly doped, silicon germanium (SiGe) or silicon deposited on the n-doped layer, and a p-doped amorphous layer of silicon deposited on the intrinsic layer.

Dangling bonds in the layers 308-316 may reduce the efficiency of the solar module 100 in converting incident light into electricity. For example, electrons or holes that are generated when the light strikes the intrinsic layers 310, 316 may become trapped and recombine at dangling bonds in the intrinsic layers 310, 316 or near the interfaces between the intrinsic layers 310, 316 and one or more of the layers 308, 312, 314, 318 on opposing sides of the intrinsic layers 310, 316. As the number of dangling bonds increases, the amount of electrons that reach the electrodes 114, 118 may decrease. As the number of electrons reaching the electrodes 114, 118 decreases, the electrical power generated by the solar cells 102 also may decrease.

The number of dangling bonds in the layers 308-318 may be reduced by the formation of bonds between the dangling bonds and hydrogen. For example, hydrogen in the deposition gases used to deposit one or more of the layers 308-318 may chemically bond with the dangling bonds. The deposition gases may include silane (SiH₄) or hydrogen gas (H₂). The hydrogen may combine with dangling silicon bonds to form SiH₂ in the layers 308-318 that include silicon. Typically, the amount of SiH₂ in the layers 308-318 is related to the amount of light-induced degradation in the cell 102. One technique for increasing the quality of an amorphous intrinsic layer in the cell 102 is to increase the ratio of SiH bonds to SiH₂ bonds. For example, the quality of the layer 316 may be increased by increasing the ratio of SiH to SiH₂ bonds. The ratio of SiH to SiH₂ bonds may be measured using FTIR.

The order in which the layers 308-312 are provided may permit the intrinsic, or lightly doped, layers in the semiconductor layer stack 116 to be deposited at higher temperatures than are used in known superstrate configuration solar modules. Increasing the deposition temperatures of the intrinsic layers in the semiconductor layer stack 116 may allow for an increased deposition rate of the intrinsic layers in the semiconductor layer stack 116 without significantly sacrificing the electronic quality of the intrinsic layers.

In accordance with one embodiment, the number of dangling bonds in one or more of the layers 308-318 may be reduced by depositing the layers 308-318 at higher deposition temperatures than is used in some known deposition methods. For example, the intrinsic layers 310, 316 may be deposited at a substrate temperature of approximately 300 to 400 degrees Celsius. Alternatively, other ones of the layers 308-318 may be deposited at higher deposition temperatures. Depositing the layers at higher deposition temperatures increases the mobility of the atoms on the deposition surface of the intrinsic layers 310, 316. As the atoms are more mobile, the atoms may be better able to find dangling bonds or open sites on the growing amorphous or microcrystalline silicon surface in the intrinsic layer 310, 316 being deposited. The atoms may bond at the dangling bonds or open sites to reduce the number of dangling bonds and open lattice sites in the intrinsic layers 310, 316 being deposited. The amount of hydrogen required to bond with the dangling bonds or open sites decreases as the number of dangling bonds or open sites decreases, as described above. In one embodiment, the percentage of SiH₂ bonds in the amorphous intrinsic layer 316 is approximately 7 atomic percent or less. In another embodiment, the percentage of SiH₂ bonds in the amorphous intrinsic layer 316 is approximately 5 atomic percent or less. In a third embodiment, the percentage of SiH₂ bonds in the amorphous intrinsic layer 316 is approximately 2.5% or less. With respect to the concentration of hydrogen in the amorphous intrinsic layer 316, the hydrogen content is approximately 21 atomic percent or less in one embodiment, approximately 15 atomic percent or less in another embodiment, and approximately 7.5 atomic percent or less in another embodiment.

The final hydrogen concentration in one or more of the layers 308-318 may be measured using Secondary Ion Mass Spectrometer (“SIMS”). A sample of one or more of the layers 308-318 is placed into the SIMS. The sample is then sputtered with an ion beam. The ion beam causes secondary ions to be ejected from the sample. The secondary ions are collected and analyzed using a mass spectrometer. The mass spectrometer then determines the molecular composition of the sample. The mass spectrometer can determine the atomic percentage of hydrogen in the sample. Alternatively, the final hydrogen concentration in one or more of the layers 308-318 may be measured using Fourier Transform Infrared spectroscopy (“FTIR”). In FTIR, a beam of infrared light is then sent through a sample of one or more of the layers 308-318. Different molecular structures and species in the sample may absorb the infrared light differently. Based on the relative concentrations of the different molecular species in the sample, a spectrum of the molecular species in the sample is obtained. The atomic percentage of hydrogen in the sample can be determined from this spectrum. Alternatively, several spectra are obtained and the atomic percentage of hydrogen in the sample is determined from the group of spectra.

The semiconductor layer stack 116 can be exposed to a focused beam of energy to remove portions of the semiconductor layer stack 116 and provide inter-semiconductor layer gaps 320 in the semiconductor layer stack 116. The focused beam of energy may include a laser light 322. The laser light 322 may be applied to laser scribe or ablate the semiconductor layer stack 116. The laser light 322 is directed into the semiconductor layer stack 116 from the film side of the solar module 100 in the illustrated embodiment. The laser light 322 may be generated as a pulsing laser light. For example, the laser light 322 may be generated for relatively short durations, such as less than 10 nanoseconds at a time. In another example, the laser light 322 may be generated for durations of less than 1000 picoseconds at a time. The laser light 322 alternatively may be provided by a non-pulsing laser light. In another embodiment, a technique other than laser scribing is used to remove portions of the semiconductor layer stack 116.

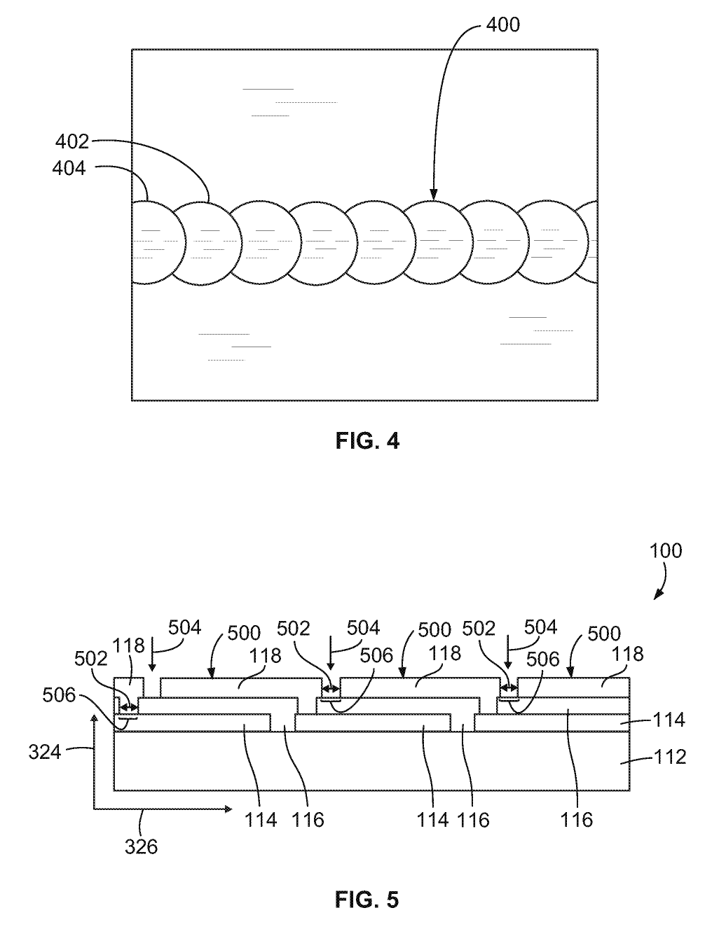

With continued reference to FIG. 3, FIG. 4 is a view of a laser scribe line 400 used to create the inter-semiconductor layer gaps 320. The laser light 322 may be pulsed by generating the laser light 322 toward the semiconductor layer stack 116 for a duration of time, removing the laser light 322 from the semiconductor layer stack 116, moving the source of the laser light 322 and the semiconductor layer stack 116 relative to one another, generating the laser light 322 toward the semiconductor layer stack 116 for a duration of time, and so on, until the laser light 322 has separated the semiconductor layer stacks 116 in neighboring cells 102. For example, the laser light 322 may laser etch an approximately circular first pulse mark 402 in the semiconductor layer stack 116 for 10 nanoseconds or less, deactivate the laser light 322, move the laser relative to the semiconductor layer stack 116, etch a second pulse mark 404 in the semiconductor layer stack 116 for 10 nanoseconds or less, and so on, until the laser scribe line 400 separates the semiconductor layer stacks 116 in adjacent cells 102 from one another. As shown in FIG. 4, the laser scribe line 400 may appear as a substantially linear line of etch marks into the semiconductor layer stack 116. The etch marks may have an approximately circular shape of the laser light or make have a different shape.

FIG. 5 is schematic illustration of the magnified view 110 of the solar module 100 at another stage of fabrication of the solar module 100. The top electrode 118 is provided above the semiconductor layer stack 116 and in the inter-semiconductor layer gap 320 (shown in FIG. 3) patterned by the laser light 322 (shown in FIG. 3). In the embodiment illustrated in FIG. 1, the top electrode 118 is deposited on the semiconductor layer stack 116 in the vertical direction 324 and between the semiconductor layer stacks 116 of adjacent cells 102 in the gaps 320 in the transverse direction 326. For example, the top electrode 118 may be sputtered or deposited using a method such as low pressure chemical vapor deposition (LPCVD) on the semiconductor layer stack 116. The top electrode 118 includes a light transmissive and conductive material. For example, the top electrode 118 may permit at least 80% of incident light on the top electrode 118 to pass through the material constituting the top electrode 118. In another example, the top electrode 118 may permit a different amount of incident light to pass through the top electrode 118. For example, the top electrode 118 may permit 60%, 40% or 20% of the incident light to pass through the top electrode 118. The amount of light transmitted may depend on the wavelength of the incident light. The top electrode 118 may be deposited as an approximately 80 nanometer to 2 micrometer thick layer of indium tin oxide (“ITO”). Alternatively, the top electrode 118 may be deposited as a layer of aluminum doped zinc oxide (Al:ZnO), boron doped zinc oxide (B:ZnO), gallium doped zinc oxide (Ga:ZnO), or another type of zinc oxide (ZnO). In another embodiment, the top electrode 118 may include a layer of ITO with a conducting grid of silver formed on a top surface 500 of the top electrode 118.

In one embodiment, the top surface 500 of the top electrode 118 is etched to increase the roughness of the top surface 500. For example, the top electrode 118 may be exposed to a chemical etch using a solution of 1% hydrogen chloride acid (HCl) and 99% water (H₂O), with the top electrode 118 exposed to the chemical etch for approximately 2 minutes or less. The top surface 500 may be roughened to increase the light trapping properties of the top electrode 118. For example, as the roughness of the top surface 500 increases, incident light that passes through the top electrode 118 and is reflected back into the top electrode 118 may internally reflect off the top surface 500 and back toward the semiconductor layer stack 116.

Portions of the top electrode 118 are removed by exposing the top electrode 118 to a patterning technique 504. The patterning technique 504 selectively removes portions of the top electrode 118 to electrically separate the top electrodes 118 in the cells 102 from one another. The patterning technique 504 is directed onto the top electrode 118 from the film side of the cell 102 and module 100. For example, the patterning technique 504 is incident on the top electrode 118 on a side of the module 100 and cell 102 that opposes the substrate 112. The upper separation gaps 502 electrically separate the top electrodes 118 of different cells 102 in the module 100, as described in more detail below. In one embodiment, the patterning technique 504 is a focused beam of energy, such as a laser light. The laser light may be applied to laser scribe the top electrode 118. In one embodiment, the laser light is generated as a pulsing laser light. For example, the laser light may be generated for relatively short durations, such as less than 10 nanoseconds at a time. In another example, the laser light may be generated for relatively short durations, such as less than 1000 picoseconds at a time. Alternatively, the laser light may be non-pulsing laser light. The laser light may generate a laser scribe similar to the laser scribe line 400 shown in FIG. 4.

Alternatively, the patterning technique 504 may include a chemical etchant. For example, an acid etchant may be directed onto the top electrode 118 in the upper separation gaps 502 by an inkjet printing apparatus. The acid etchant may remove the top electrode 118 in the upper separation gaps 502. In another embodiment, a sacrificial light-absorbing layer may be provided as the patterning technique 504 between the semiconductor layer stack 116 and the top electrode 118. The light-absorbing layer may be deposited using an inkjet printing apparatus that deposits the absorbing layer in the upper separation gaps 502 between the semiconductor layer stack 116 and the top electrode 118 before the top electrode 118 is deposited. The absorbing layer may absorb the laser light when irradiated from the film side using a wavelength at which the transparent electrode is transparent. This can then cause the transparent electrode to be ablated from above the sacrificial light-absorbing layer. The combination of the absorbing layer and top electrode 118 then may be removed by laser scribing in order to remove the top electrode 118 in the upper separation gaps 502. In another example, mechanical scribing or photolithography may be used to remove the top electrode 118 in the upper separation gaps 502.

As described above, significant interdiffusion between the electrode 118 and the semiconductor layer stack 116 may result in an electrical short or a conductive bridge between the top electrodes 118 in adjacent cells 102. Alternatively, significant interdiffusion within the n-doped, intrinsic, and p-doped sublayers of semiconductor layer stack 116 may result in an electrical short or a conductive bridge between the top electrode 118 and reflective electrode 114 in individual cells 102. The laser light 322 or other source of energy is generated towards the semiconductor layer stack 116 and or top electrode for relatively short durations, or pulses, in order to remove the top electrode 118 in the upper separation gaps 502 while not greatly increasing the amount of heat dissipated in the top electrode 118 and/or semiconductor layer stack 116. For example, the laser light 504 may be generated over very short pulses to avoid imparting sufficient thermal energy into the top electrode 118 and the semiconductor layer stack 116 to cause conductive pathways to form via interdiffusion between adjacent top electrodes 118 or between top electrodes 118 and reflective electrodes 114. Reducing the amount of interdiffusion between the top electrode 118 and the semiconductor layer stack 116 may result in a sufficiently large impedance or resistance remaining between the top electrodes 118 in adjacent cells 102 and between the top electrodes 118 and reflective electrodes 114 in individual cells 102.

An electrically isolating area 506 of the semiconductor layer stack 116 that extends between the top electrodes 118 in adjacent cells 102 electrically separates the top electrodes 118 in adjacent cells 102 from one another. The upper separation gaps 502 may separate the top electrodes 118 in neighboring cells 102 by the electrically separating area 506 such that an electrical short between the top electrodes 118 is avoided. By way of example only, the upper separation gaps 502 may separate the top electrodes 118 from one another such that no conductive pathway having an area-specific resistance of less than 500 ohms*cm² exists between the top electrodes 118 in adjacent cells 102 when the voltage difference between the top and bottom electrodes 118, 114 in each of the adjacent cells 102 is between approximately −0.1 and 0.1 volts. In another example, the upper separation gaps 502 may separate the top electrodes 118 from one another such that no conductive pathway having an area-specific resistance of less than 1000 ohms*cm² exists between the top electrodes 118 in adjacent cells 102 when the voltage difference between the top and bottom electrodes 118, 114 in each of the adjacent cells 102 is between approximately −0.1 and 0.1 volts. In another example, the upper separation gaps 502 may separate the top electrodes 118 from one another such that no conductive pathway having an area-specific resistance of less than 2000 ohms*cm² exists between the top electrodes 118 in adjacent cells 102 when the voltage difference between the top and bottom electrodes 118, 114 is between approximately −0.1 and 0.1 volts. Alternatively, the electrical resistance the electrically separating area 506 may be a greater amount.

Returning to FIG. 1, a layer of an adhesive material 120 is provided above the top electrode 118 and above the semiconductor layer stack 116 in the inter-semiconductor layer gaps 320 where the semiconductor layer stack 116 was removed. For example, the adhesive layer 120 may be deposited on the semiconductor layer stack 116 in the inter-semiconductor layer gaps 320 and on the top electrode 118. The adhesive layer 120 may include a material such as a polyvinyl butyral (“PVB”), surlyn, or ethylene-vinyl acetate (“EVA”) copolymer, for example. A cover sheet 120 of light transmissive material is then placed above the adhesive layer 120. For example, the cover sheet 120 may be placed on the adhesive layer 120. The cover sheet 122 includes or is formed from a light transmissive material, or a transparent or translucent material such as glass. For example, the cover sheet 122 may include tempered glass. Alternatively, the cover sheet 122 can include soda-lime glass, low-iron tempered glass, or low-iron annealed glass. The use of tempered glass in the cover sheet 122 may help to protect the module 100 from physical damage. For example, a tempered glass cover sheet 122 may help protect the module 100 from hailstones and other environmental damage. Prior to lamination of the top glass cover sheet, the module 100 may be cut into smaller sizes than 2.2 meters by 2.6 meters, or other similar dimensions, for use in different photovoltaic applications.

One or more embodiments described herein provide a monolithically integrated solar module. The modules described herein may include a substrate configuration solar module that deposits the intrinsic layers of the semiconductor layer stacks prior to depositing the p-doped layers. Depositing the p-doped layers after the intrinsic layers allows the intrinsic layers to be deposited at higher temperatures than in known superstrate configuration solar modules. Moreover, depositing the p-doped layers after the intrinsic layers may reduce the interdiffusion between the p-doped layers and intrinsic layers. In some embodiments, the solar cells may be electrically isolated from one another by exposing the top electrodes to a source of energy while avoiding significant interdiffusion of the top electrode and semiconductor layer stack. Avoiding the significant interdiffusion of the top electrode and the semiconductor layer stack may prevent electrical shorts between the top electrodes in adjacent cells.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and merely are example embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

1. A solar module comprising:
a non-conducting substrate;
a plurality of electrically interconnected solar cells provided above the substrate, at least one of the solar cells comprising:
a reflective electrode provided above the substrate;
a silicon layer stack comprising an n-doped layer provided above the reflective electrode, an intrinsic layer provided above the n-doped layer and a p-doped layer provided above the intrinsic layer; and
a light transmissive electrode provided above the silicon layer stack; and
an upper separation gap provided between the cells, the upper separation gap electrically separating the light transmissive electrodes in the solar cells from one another, wherein the light transmissive electrode of one of the solar cells is electrically connected to the reflective electrode of another one of the solar cells.

2. The solar module of claim 1, wherein the plurality of solar cells comprises at least 25 solar cells electrically connected in series.

3. The solar module of claim 1, wherein the upper separation gap exposes the silicon layer stack between the light transmissive electrodes in the solar cells.

4. The solar module of claim 1, wherein an area of the silicon layer stack that extends between the light transmissive electrodes in the separation gap has an area-specific electrical shunt resistance that is at least approximately 1000 ohms*cm² when a voltage difference between the reflective electrodes and the light transmissive electrodes in adjacent solar cells is between −0.1 and 0.1 volts.

5-7. (canceled)

8. The solar module of claim 1, wherein the silicon layer stack is provided as a microcrystalline silicon layer stack.

9. The solar module of claim 1, wherein the silicon layer stack comprises a bottom layer stack of the n-doped layer, the intrinsic layer and the p-doped layer, the silicon layer stack further comprising a top layer stack provided above the bottom layer stack, the top layer stack comprising a top stack n-doped layer, a top stack intrinsic layer provided above the top stack n-doped layer, and a top stack p-doped layer provided above the top stack intrinsic layer.

10. The solar module of claim 9, further comprising an interlayer disposed between the bottom layer stack and the top layer stack, the interlayer at least partially reflecting incident light back into the top layer stack.

11. (canceled)

12. The solar module of claim 1, wherein the intrinsic layer has a content of SiH₂ that is approximately 2.5 atomic percent or less.

13. The solar module of claim 1, further comprising an inter-silicon layer gap provided between the solar cells, the inter-silicon layer gap separating the light transmissive electrodes in adjacent solar cells, wherein the inter-silicon layer gap includes a laser scribe line having a substantially linear line of circular ablation marks.

14. A method for manufacturing a solar module having a plurality of electrically interconnected solar cells, the method comprising:
providing a substrate, a reflective electrode, a silicon layer stack and a light transmissive electrode, the silicon layer stack comprising an n-doped layer provided above the reflective electrode, an intrinsic layer provided above the n-doped layer and a p-doped layer provided above the intrinsic layer; and
removing a portion of the light transmissive electrode to electrically separate the light transmissive electrodes in the solar cells from one another, wherein the portion is removed by exposing the light transmissive electrode to a patterning technique from a side of the solar module that opposes the substrate.

15. The method of claim 14, wherein the patterning technique comprises laser light.

16. The method of claim 14, wherein the patterning technique comprises a laser light that is pulsed for durations of approximately 1000 picoseconds or less.

17. (canceled)

18. The method of claim 14, wherein removing the portion of the light transmissive electrode exposes an area of the silicon layer stack between the solar cells, the exposed area having an area-specific electrical resistance that is at least approximately 1000 ohms*cm² when a voltage difference between the reflective electrodes and the light transmissive electrodes in adjacent solar cells is between −0.1 and 0.1 volts.

19. (canceled)

20. The method of claim 14, wherein providing comprises providing the reflective electrode above the substrate, providing the silicon layer stack above the reflective electrode, and providing the light transmissive electrode above the silicon layer stack.

21. The method of claim 14, wherein providing comprises depositing the intrinsic layer of the silicon layer stack at a greater temperature than the p-doped layer of the silicon layer stack.

22. A solar module comprising:
a non-conducting substrate;
a plurality of electrically interconnected solar cells provided above the substrate, at least one of the solar cells comprising:
a reflective electrode provided above the substrate;
a bottom silicon layer stack comprising an N-I-P layer stack deposited above the reflective electrode;
a top silicon layer stack comprising an N-I-P layer stack deposited above the bottom silicon layer stack; and
a light transmissive electrode provided above the top silicon layer stack; and
an upper separation gap provided between the cells, the upper separation gap electrically separating the light transmissive electrodes in the solar cells from one another, wherein the light transmissive electrode of one of the solar cells is electrically connected to the reflective electrode of another one of the solar cells.

23. The solar module of claim 22, wherein both the bottom silicon layer stack and the top silicon layer stack comprises an amorphous N-I-P layer stack.

24. The solar module of claim 22, wherein the bottom silicon layer stack is a microcrystalline N-I-P layer stack and the top silicon layer stack is an amorphous N-I-P layer stack.

25. The solar module of claim 22, wherein an area of the top silicon layer stack that extends between the light transmissive electrodes in the upper separation gap has an area-specific electrical shunt resistance that is at least approximately 1000 ohms*cm² when a voltage difference between the reflective electrodes and the light transmissive electrodes in adjacent solar cells is between −0.1 and 0.1 volts.

26. The solar module of claim 22, further comprising an inter-semiconductor layer gap provided between the solar cells, the inter-semiconductor layer gap separating the light transmissive electrodes in the solar cells from one another, wherein the inter-semiconductor layer gap includes a laser scribe line.
